(19) United States
(12) Patent Application Publication
(10) Pub. No.: US 2025/0022833 A1
(43) Pub. Date: Jan. 16, 2025

(54) SEMICONDUCTOR MODULE, SEMICONDUCTOR DEVICE, AND VEHICLE

(71) Applicant: FUJI ELECTRIC CO., LTD., Kawasaki-shi (JP)

(72) Inventors: Yoko NAKAMURA, Kawasaki-shi (JP); Akihiko IWAYA, Kawasaki-shi (JP); Mai SAITO, Kawasaki-shi (JP); Tsubasa WATAKABE, Kawasaki-shi (JP); Yuta TAMAI, Kawasaki-shi (JP)

(73) Assignee: FUJI ELECTRIC CO., LTD., Kawasaki-shi (JP)

(21) Appl. No.: 18/902,281

(22) Filed: Sep. 30, 2024

Related U.S. Application Data
(63) Continuation of application No. PCT/JP2023/031781, filed on Aug. 31, 2023.

(30) Foreign Application Priority Data
Oct. 25, 2022 (JP) 2022-170593

(51) Int. Cl. H01L 23/00; H01L 23/31

(52) U.S. Cl. CPC H01L 24/37; H01L 23/3135; H01L 24/40; H01L 24/32; H01L 24/73; H01L 2224/32227; H01L 2224/37011; H01L 2224/37013; H01L 2224/40229; H01L 2224/73263; H01L 2924/35121

(57) ABSTRACT

A semiconductor module, including: a circuit board including a semiconductor element; a lead bonded to an electrode of the semiconductor element by a bonding material; and a sealing material sealing the semiconductor element and the lead. The lead includes: a bonding portion bonded to the electrode, and a roughening recess formed on an upper surface of the bonding portion. The roughening recess includes: a main recess having a first wall surfaces and a second wall surface opposite to each other, and a barbed portion formed on the first wall surface and protruding toward the second wall surface, and a sub-recess having: a center, which is located, in a plan view of the semiconductor module, outside the main recess and at a position away from the first wall surface by a predetermined distance, and an inclined surface that becomes shallower from the center toward an opening end of the main recess.

### CROSS-REFERENCE TO RELATED APPLICATIONS

This application is a continuation application of PCT Application No. PCT/JP2023/031781, filed Aug. 31, 2023, which claims the benefit of priority to Japanese Patent Application No. 2022-170593, filed Oct. 25, 2022, each of which is incorporated by reference herein in its entirety.

### TECHNICAL FIELD

The present invention relates to a semiconductor module, a semiconductor device, and a vehicle.

### BACKGROUND ART

Some power conversion devices such as an inverter device include a semiconductor device including a circuit board on which a semiconductor element such as an insulated gate bipolar transistor (IGBT), a power metal oxide semiconductor field effect transistor (power MOSFET), and a free wheeling diode (FWD) is mounted. The circuit board includes a wiring board in which a conductor pattern is provided on a surface of an insulating substrate, and a circuit component such as a semiconductor element disposed on the wiring board.

In this type of semiconductor device, a conductor plate called a lead or the like may be used as a conductive member that electrically connects an electrode provided on a surface (upper surface) on a side opposite to a surface facing a wiring board side in electrodes of the semiconductor element and the conductor pattern of the wiring board.

In the semiconductor device in which the electrode of the semiconductor element and the conductor pattern of the wiring board are electrically connected using the lead, various measures have been proposed in order to prevent delamination at an interface between the lead and a sealing material.

For example, Patent Literature 1 describes a resin-sealed semiconductor device in which a plurality of recesses is disposed vertically and horizontally at substantially equal intervals in a portion other than a flat semiconductor element mounting region on a surface of a metal plate to which a semiconductor element is fixed, and each of the plurality of recesses is two rectangular recesses offset in a diagonal direction.

In addition, for example, Patent Literature 2 describes a semiconductor device in which a side wall of a dimple formed in a lead frame has a barb portion protruding inward, and the dimples communicate with each other by a groove portion. In addition, for example, Patent Literature 3 describes a semiconductor device in which a barbed portion obtained by a part of an inner peripheral wall protruding inward is formed in each of a plurality of dimples formed in a lead frame, and the plurality of dimples includes two types of dimples having different orientation of the barbed portion.

In addition, for example, Patent Literature 4 describes a semiconductor device in which a large dimple opening at least one main surface and a small dimple opening on the inner surface of the large dimple are formed on the main surface of a die pad in a lead frame.

In addition, for example, Patent Literature 5 describes a semiconductor device in which a plurality of rectangular recesses is disposed vertically and horizontally at substantially equal intervals in a portion other than a semiconductor element mounting region on a surface of a metal plate to which a semiconductor element is fixed.

### CITATION LIST

### Patent Literature

Patent Literature 1: JP 3748849 B2
Patent Literature 2: JP 4086774 B2
Patent Literature 3: JP 2017-005124 A
Patent Literature 4: JP 2015-060889 A
Patent Literature 5: JP 2004-186622 A

### SUMMARY OF INVENTION

### Technical Problem

In the above-described configuration for preventing delamination at the interface between the lead and the sealing material in the semiconductor device, when a recess called a dimple, a barbed portion, or the like formed on the surface of the lead is formed by press working, an external force in a direction orthogonal to the surface of the lead is applied to the lead to deform the conductive material as the lead. When the barbed portion is formed by such press working, it is difficult to form the recess and the barbed portion with dimensions required to prevent delamination of the sealing material due to limitations of working dimensions and the like.

The present invention has been made in view of such a point, and one object is to prevent delamination at an interface between a lead bonded to an electrode of a semiconductor element by a bonding material and a sealing material.

### Solution to Problem

A semiconductor module according to one aspect of the present invention includes: a circuit board on which a semiconductor element is mounted; a lead that is bonded to an electrode on an upper surface of the semiconductor element by a bonding material; and a sealing material that seals the semiconductor element and the lead, in which in the lead, a roughening recess that prevents delamination at an interface between the lead and the sealing material is formed on an upper surface of a bonding portion bonded to the electrode, the upper surface being opposite to a lower surface facing the electrode, and the roughening recess includes a main recess in which a barbed portion protruding toward an opposite wall surface is formed on one or more wall surfaces of a recess and a sub-recess having a center located outside the main recess in plan view and at a position away from the wall surface on which the barbed portion is formed by a predetermined distance, and having an inclined surface that becomes shallower from the center toward an opening end of the main recess.

### Advantageous Effects of Invention

According to the present invention, it is possible to prevent delamination at an interface between a lead bonded to an electrode of a semiconductor element by a bonding material and a sealing material.

### BRIEF DESCRIPTION OF DRAWINGS

FIG. 1 is a top view illustrating a configuration example of a semiconductor device according to an embodiment.

FIG. 2 is a cross-sectional view taken along line A-A′ of the semiconductor device in FIG. 1.

FIG. 3 is an enlarged partial top view of a region R in FIG. 1.

FIG. 4 is an enlarged partial top view of one of roughening recesses formed in the portion illustrated in FIG. 3.

FIG. 5 is a cross-sectional view taken along line B-B′ in FIG. 4.

FIG. 6 is a view describing an example of formation positions and dimensions of recesses to be main recesses and sub-recesses.

FIG. 7 is a perspective view exemplifying a punch used for forming a recess to be a main recess.

FIG. 8 is a partial top view exemplifying recesses formed in a first bonding portion of a lead by the punch exemplified in FIG. 7.

FIG. 9 is a cross-sectional view taken along line C-C′ in the portion of the first bonding portion illustrated in FIG. 8.

FIG. 10 is a perspective view exemplifying a punch used for forming the sub-recess.

FIG. 11 is a partial top view exemplifying sub-recesses formed in the first bonding portion of the lead by the punch exemplified in FIG. 10.

FIG. 12 is a cross-sectional view taken along line C-C′ in the portion of the first bonding portion illustrated in FIG. 11.

FIG. 13 is a partial top view exemplifying the first bonding portion in which a second sub-recess is formed at each recess.

FIG. 14 is a cross-sectional view taken along line C-C′ in the portion of the first bonding portion illustrated in FIG. 13.

FIG. 15 is a partial top view exemplifying the first bonding portion in which a third sub-recess is formed at each recess.

FIG. 16 is a partial top view exemplifying the first bonding portion in which a fourth sub-recess is formed at each recess.

FIG. 17 is a perspective view illustrating another example of a punch used for forming the sub-recess.

FIG. 18 is a partial top view describing a first modification of arrangement of roughening recesses.

FIG. 19 is a partial top view describing a second modification of arrangement of roughening recesses.

FIG. 20 is a partial top view describing a third modification of arrangement of roughening recesses.

FIG. 21 is a partial top view describing a fourth modification of arrangement of roughening recesses.

FIG. 22 is a partial top view describing a fifth modification of arrangement of roughening recesses.

FIG. 23 is a schematic plan view illustrating an example of a vehicle to which the semiconductor device according to the present invention is applied.

### DESCRIPTION OF EMBODIMENTS

Hereinafter, an embodiment of the present invention will be described in detail with reference to the drawings. Note that the X, Y, and Z axes in each of the drawings to be referred to are illustrated for the purpose of defining a plane and a direction in an exemplified semiconductor device or the like, and the X, Y, and Z axes are orthogonal to each other and form a right-handed coordinate system. In the following description, the X direction may be referred to as a left-right direction, the Y direction may be referred to as a front-rear direction, and the Z direction may be referred to as an up-down direction. In addition, a plane including the X axis and the Y axis may be referred to as an XY plane, a plane including the Y axis and the Z axis may be referred to as a YZ plane, and a plane including the Z axis and the X axis may be referred to as a ZX plane. These directions (front-rear, left-right, and up-down directions) and planes are terms used for convenience of description, and a correspondence relationship with the XYZ directions may change depending on an attachment orientation of the semiconductor device. For example, a heat dissipation surface side (cooler side) of the semiconductor device is referred to as a lower surface side, and the opposite side is referred to as an upper surface side. In addition, in the present specification, plan view means a case where an upper surface or a lower surface (XY plane) of the semiconductor device or the like is viewed from the Z direction. In addition, an aspect ratio and a size relationship between the members in each drawing are merely schematically represented, and do not necessarily coincide with a relationship in a semiconductor device or the like actually manufactured. For convenience of description, it is also assumed that the size relationship between the members is exaggerated.

In addition, the semiconductor device exemplified in the following description is applied to, for example, a power conversion device such as an inverter of an industrial or in-vehicle motor. Thus, in the following description, detailed description of the same or similar configuration, function, operation, and the like as those of the known semiconductor device will be omitted.

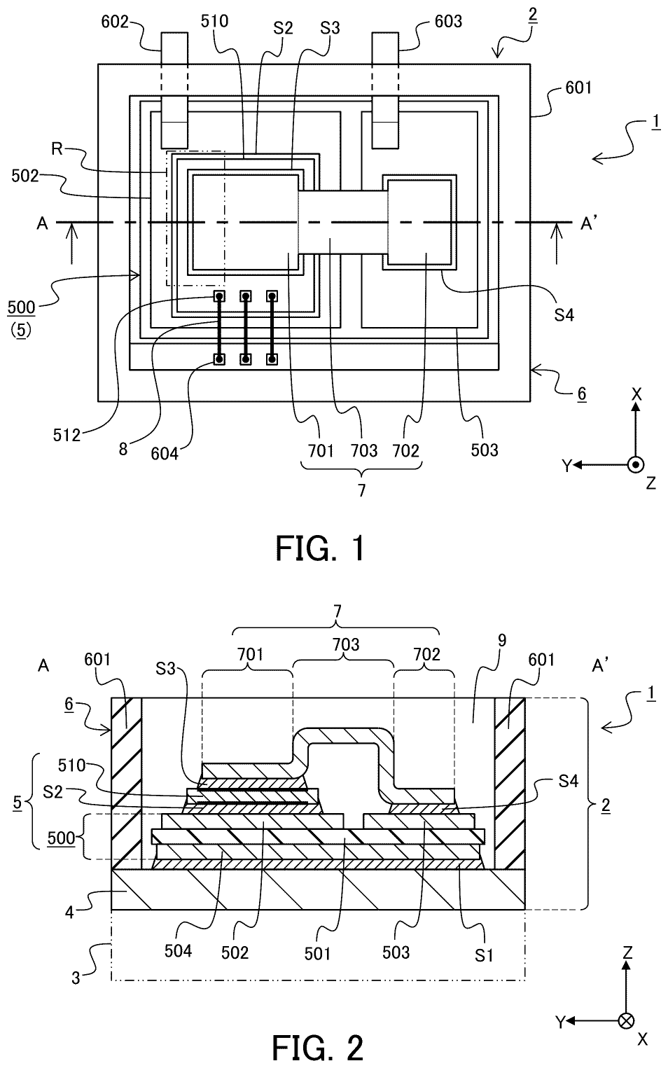

FIG. 1 is a top view illustrating a configuration example of a semiconductor device according to an embodiment. FIG. 2 is a cross-sectional view taken along line A-A′ of the semiconductor device in FIG. 1. In FIG. 1, a sealing material filling a case is omitted. In addition, in FIG. 2, hatching indicating a cross section of the sealing material filling the case is omitted.

As exemplified in FIGS. 1 and 2, a semiconductor device 1 according to the present embodiment is configured by disposing a semiconductor module 2 on an upper surface of a cooler 3. Note that the cooler 3 is an arbitrary configuration with respect to the semiconductor module 2.

The cooler 3 dissipates heat of the semiconductor module 2 to the outside and has a rectangular parallelepiped shape as a whole. Although not particularly illustrated, the cooler 3 is configured by providing a plurality of fins on a lower surface side of a flat plate-shaped base portion and housing these fins in a water jacket. Note that the shape and the configuration of the cooler 3 are not limited thereto, and can be appropriately changed.

The semiconductor module 2 includes a base 4, a circuit board 5, a case 6, a lead 7, bonding materials S1 to S4, bonding wires 8, and a sealing material 9.

The base 4 is a substrate on which the circuit board 5 is mounted, and the base 4 on which the circuit board 5 is mounted is attached to a lower surface of the case 6 with the surface on which the circuit board 5 is mounted facing upward. The case 6 includes an insulating member 601 having a rectangular annular shape whose upper surface and lower surface are opened, main terminals 602 and 603 integrated with the insulating member 601, and a plurality of control terminals 604. The circuit board 5 mounted on the base 4 is housed in a hollow portion of the insulating member 601 of the case 6. The base 4 is, for example, a metal plate such as a copper plate or an aluminum plate, and conducts heat generated in the circuit board 5 to the cooler 3. This type of base 4 may be referred to as a heat dissipation plate or a heat dissipation layer. The base 4, which is a heat dissipation plate, may be disposed on the upper surface of the cooler 3, for example, via a thermal conductive material such as a thermal grease or a thermal compound. In the semiconductor module 2, the base 4 may be omitted, and the lower surface (a conductor pattern 504 of a wiring board 500 exemplified in FIG. 2) of the circuit board 5 may be bonded to the cooler 3.

The circuit board 5 includes the wiring board 500 and a semiconductor element 510 mounted on an upper surface of the wiring board 500. The wiring board 500 includes an insulating substrate 501, conductor patterns 502 and 503 provided on an upper surface of the insulating substrate 501, and the conductor pattern 504 provided on a lower surface of the insulating substrate 501. The wiring board 500 may be, for example, a direct copper bonding (DCB) substrate or an active metal brazing (AMB) substrate. The wiring board 500 may be referred to as a stacked substrate.

The insulating substrate 501 is not limited to a specific substrate. The insulating substrate 501 may be, for example, a ceramic substrate made of a ceramic material such as aluminum oxide (Al₂O₃), aluminum nitride (AlN), silicon nitride (Si₃N₄), aluminum oxide (Al₂O₃), and zirconium oxide (ZrO₂). The insulating substrate 501 may be, for example, a substrate obtained by molding an insulating resin such as epoxy resin, a substrate obtained by impregnating a base material such as a glass fiber with an insulating resin, a substrate obtained by coating a surface of a flat plate-shaped metal core with an insulating resin, or the like.

The conductor patterns 502 and 503 provided on the upper surface of the insulating substrate 501 are conductive members used as wiring members in the circuit board 5, and the conductor pattern 504 provided on the lower surface of the insulating substrate 501 is a conductive member used as a heat dissipation member that conducts heat generated in the circuit board 5 to the base 4. These conductor patterns 502 to 504 are formed of, for example, a metal plate such as copper or aluminum. The conductor pattern 504 provided on the lower surface of the insulating substrate 501 is bonded to the upper surface of the base 4 by the bonding material S1 such as solder. The conductor patterns 502 and 503 provided on the upper surface of the insulating substrate 501 may be each referred to as a conductor layer, a conductor plate, or a wiring pattern. The conductor pattern 504 provided on the lower surface of the insulating substrate 501 may be referred to as a heat dissipation layer, a heat dissipation plate, or a heat dissipation pattern.

As described above, the conductor patterns 502 and 503 provided on the upper surface of the insulating substrate 501 are conductive members used as wiring members in the circuit board 5. In the semiconductor module 2 exemplified in FIGS. 1 and 2, the semiconductor element 510 is mounted on the upper surface of the first conductor pattern 502. In the semiconductor element 510, a first main electrode (not illustrated) provided on the lower surface is bonded to the first conductor pattern 502 by the bonding material S2.

A second main electrode (not illustrated) and control electrodes 512 are provided on the upper surface of the semiconductor element 510. These electrodes are electrically insulated by an insulating layer (not illustrated) formed on the upper surface of the semiconductor element 510. The insulating layer may be a surface protective film such as a passivation film formed on the upper surface of the semiconductor element 510. The second main electrode is electrically connected, via the lead 7, to the second conductor pattern 503 provided on the upper surface of the insulating substrate 501. The lead 7 includes a first bonding portion 701, a second bonding portion 702, and a wiring portion 703 connecting the first bonding portion 701 and the second bonding portion 702. The first bonding portion 701 is electrically connected to the second main electrode of the semiconductor element 510 by the bonding material S3. The second bonding portion 702 is bonded to the second conductor pattern 503 of the wiring board 500 by the bonding material S4. The control electrodes 512 on the upper surface of the semiconductor element 510 are electrically connected, via the bonding wires 8, to the control terminals 604 provided on the case 6.

In the semiconductor module 2 exemplified in FIGS. 1 and 2, the first conductor pattern 502 is electrically connected to the first main terminal 602 provided in the case 6, and the second conductor pattern 503 is electrically connected to the second main terminal 603 provided in the case 6. It is sufficient if a method of electrically connecting the first conductor pattern 502 and the first main terminal 602 and electrically connecting the second conductor pattern 503 and the second main terminal 603 is any of known connection methods, and the method is not limited to a specific method. In addition, the shapes and positions of the main terminals 602 and 603, the number, positions, and the like of the control terminals 604 in the case 6 are not limited to those illustrated, and can be changed as appropriate. Further, the case 6 of the semiconductor module 2 of the present embodiment may be provided with a third main terminal, which is not illustrated, and the like.

In the present embodiment, the semiconductor element 510 includes, for example, a reverse conducting (RC)-IGBT element in which the functions of an insulated gate bipolar transistor (IGBT) element and a free wheeling diode (FWD) element are integrated.

Note that the semiconductor element mounted on the upper surface of the wiring board 500 is not limited to a specific one. A semiconductor element as a switching element such as the IGBT or the power metal oxide semiconductor field effect transistor (MOSFET) and a semiconductor element as a diode element such as the FWD may be mounted on the upper surface of the wiring board 500. In addition, a reverse blocking (RB)-IGBT or the like having a sufficient withstand voltage against a reverse bias may be used as the semiconductor element. The semiconductor element is formed of a semiconductor substrate such as silicon (Si) or silicon carbide (SiC) in a rectangular shape in plan view. Note that the shape, disposition number, disposition location, and the like of the semiconductor element can appropriately be changed. The layout of the conductor pattern as the wiring member provided on the upper surface side of the wiring board 500 is changed according to the type and shape of the semiconductor element to be mounted, the number of the semiconductor elements to be disposed, the location of the semiconductor elements to be disposed, and the like.

When the switching element of the semiconductor element 510 is the IGBT element, the second main electrode on the upper surface side may be referred to as an emitter electrode, and the first main electrode on the lower surface side may be referred to as a collector electrode. When the switching element of the semiconductor element 510 is the MOSFET element, the second main electrode on the upper surface side may be referred to as a source electrode, and the first main electrode on the lower surface side may be referred to as a drain electrode. In addition, the control electrodes 512 provided on the upper surface of the semiconductor element 510 may include a gate electrode and an auxiliary electrode. For example, the auxiliary electrode may be an auxiliary emitter electrode or an auxiliary source electrode electrically connected to the second main electrode and serving as a reference potential with respect to a gate potential. In addition, the auxiliary electrode may be a temperature sensing electrode that is electrically connected to a temperature sensing portion and measures the temperature of the semiconductor element 510. Such electrodes (the second main electrode and the control electrodes 512 including a gate electrode and an auxiliary electrode) formed on the upper surface of the semiconductor element 510 may be generally referred to as upper surface electrodes.

The lead 7 described above is formed by bending a metal plate such as a copper plate, and may be referred to as a lead frame or a metal wiring board. On the upper surface of the semiconductor element 510, an insulating layer is formed so as to surround the second main electrode electrically connected to the first bonding portion 701 of the lead 7. The spread of the bonding material S3 with which the second main electrode and the first bonding portion 701 of the lead 7 are bonded is restricted in a plane (XY plane) at the time of melting by the insulating layer surrounding the second main electrode.

An end portion of the wiring portion 703 of the lead 7 on the first bonding portion 701 side is connected to one side surface of the first bonding portion 701 and is bent from the side surface in a direction opposite to a lower surface (in other words, a surface of the first bonding portion 701 facing the second main electrode of the semiconductor element 510) of the first bonding portion 701. Similarly, an end portion of the wiring portion 703 of the lead 7 on the second bonding portion 702 side is connected to one side surface of the second bonding portion 702 and is bent from the side surface in a direction opposite to a lower surface (in other words, a surface of the second bonding portion 702 facing the conductor pattern 503) of the second bonding portion 702.

The semiconductor element 510, the lead 7, the bonding wires 8, and the like housed in the case 6 are sealed by the sealing material 9. The sealing material 9 may be a single insulating material or a combination of a plurality of types of insulating materials having different compositions (characteristics). For example, the sealing material 9 may contain a coating agent such as polyamide (PA) to be coated on the surfaces of the semiconductor element 510, the lead 7, and the like, and an insulating material such as an epoxy resin to be additionally loaded after coating using the coating agent.

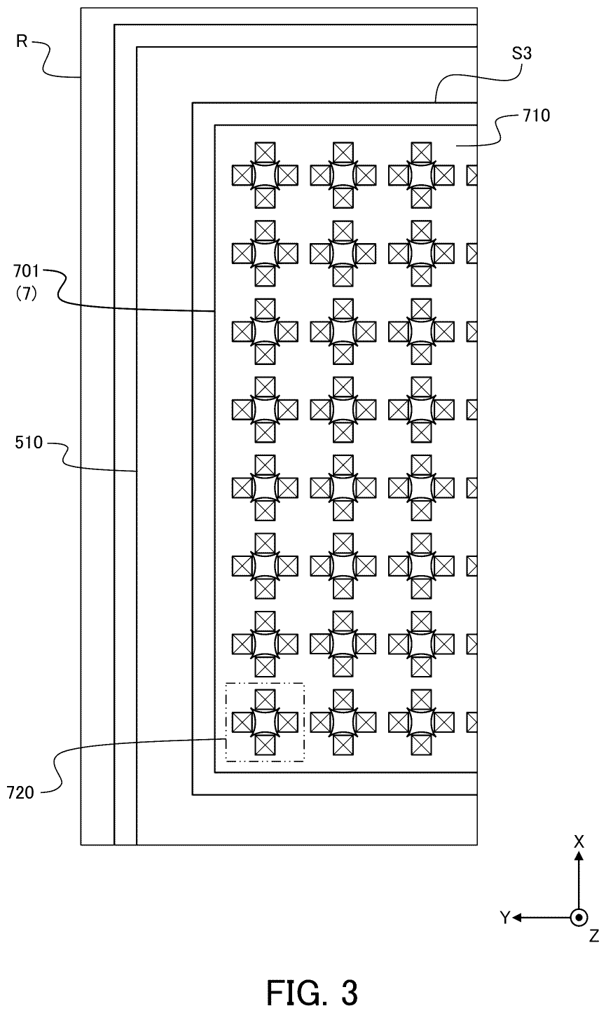

Although not illustrated in FIG. 1, in the semiconductor device 1 of the present embodiment, for example, the upper surface (the surface opposite to the surface facing the semiconductor element 510) of the first bonding portion 701 of the lead 7 is subjected to a roughening treatment for preventing delamination at the interface between the first bonding portion 701 and the sealing material 9. Specifically, a plurality of recesses (hereinafter referred to as “roughening recesses”) is provided on the upper surface of the first bonding portion 701. A first example of the plurality of roughening recesses provided on the upper surface of the first bonding portion 701 will be described below with reference to FIGS. 3 to 5.

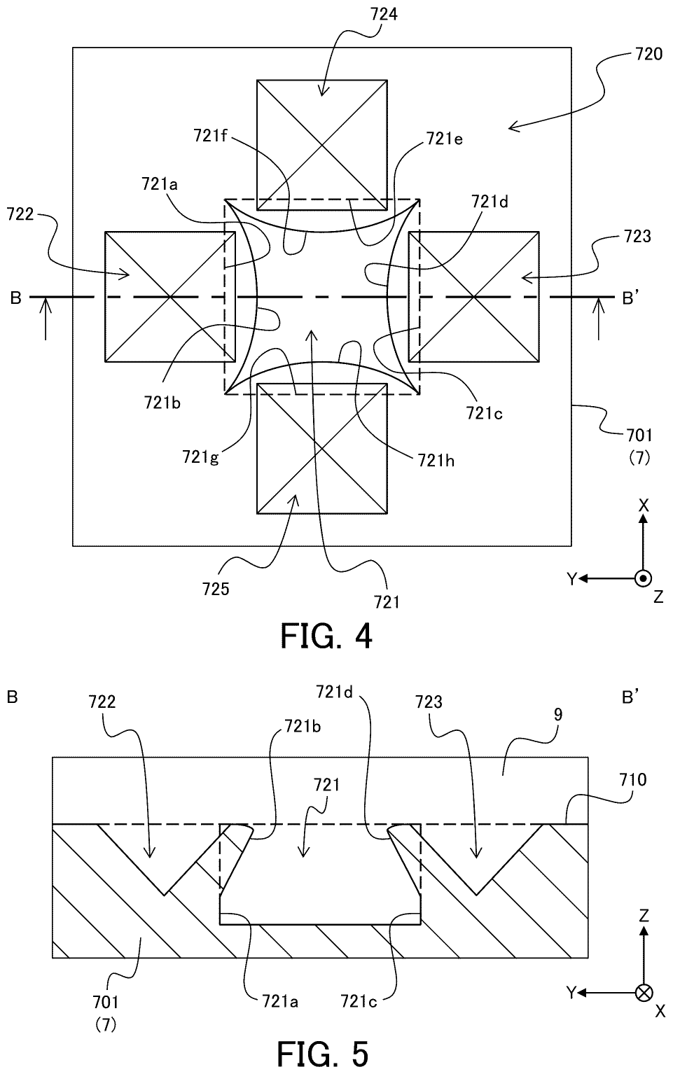

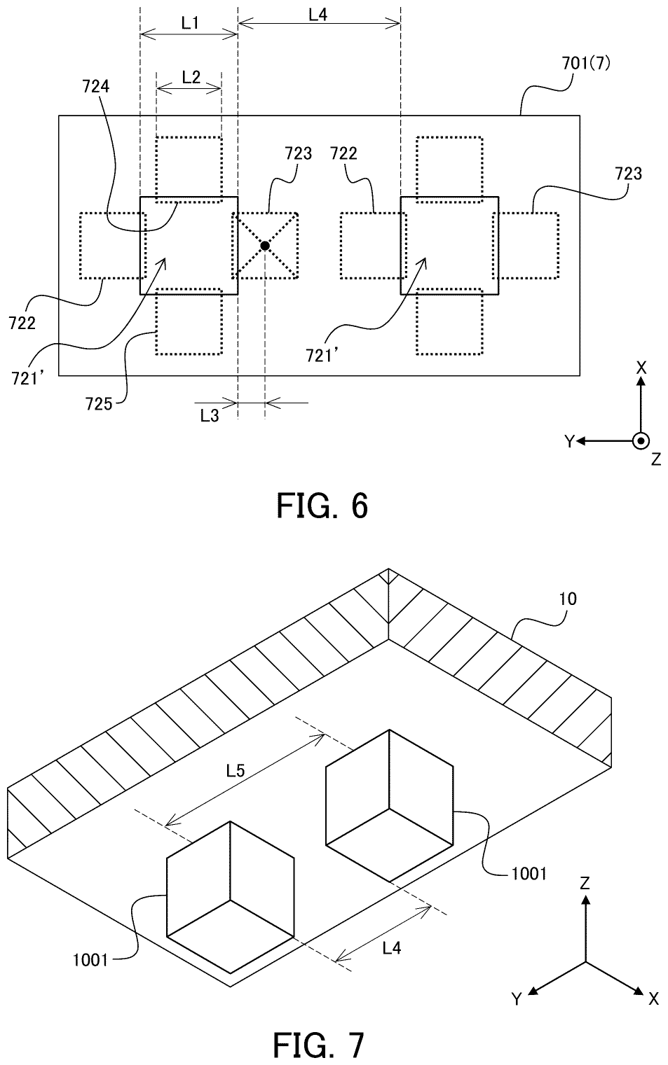

FIG. 3 is an enlarged partial top view of a region R in FIG. 1. FIG. 4 is an enlarged partial top view of one of roughening recesses (720) formed in the portion illustrated in FIG. 3. FIG. 5 is a cross-sectional view taken along line B-B′ in FIG. 4. FIG. 6 is a view describing an example of formation positions and dimensions of recesses to be main recesses and sub-recesses. In FIGS. 3 and 4, the sealing material 9 that is loaded in the case 6 and overlaps the first bonding portion 701 of the lead 7 is omitted. In addition, the cross-sectional view of FIG. 5 illustrates only a part of the upper surface side of the first bonding portion 701 and a part of the sealing material 9, and hatching illustrating a cross section of the sealing material 9 loaded in the case 6 is omitted.

In the first example of the roughening recess formed on an upper surface 710 of the first bonding portion 701, one roughening recess 720 includes a main recess 721 and four sub-recesses 722 to 725 as exemplified in FIGS. 3 and 4. As will be described below with reference to FIGS. 6 and 7 to 9, the main recess 721 is obtained by deforming a recess 721′ defining a quadrangular prism-shaped space having a flat bottom surface formed on the upper surface 710 of the first bonding portion 701 using the four sub-recesses 722 to 725. Each of the four sub-recesses 722 to 725 is a recess having a quadrangular opening end and defining a quadrangular pyramid-shaped space having the opening end as a bottom surface, and is formed so as to deform one wall surface of the recess 721′ to be the main recess 721 toward the opposing wall surface by one surface of the quadrangular pyramid. One sub-recess (for example, in FIGS. 4 and 5, the sub-recess 722 located on the left side (positive side in the Y direction) of the main recess 721) deforms the left wall surface 721a of the recess 721′ rightward (negative side in the Y direction), whereby a barbed portion 721b is formed on the wall surface 721a. Another sub-recess (for example, in FIGS. 4 and 5, the sub-recess 723 located on the right side of the main recess 721) deforms the right wall surface 721c of the recess 721′ leftward, whereby a barbed portion 721d is formed on the wall surface 721c. In addition, in FIG. 4, the sub-recess 724 located on the upper side (positive side in the X direction) of the main recess 721 deforms the upper wall surface 721e of the recess 721′ downward (negative side in the X direction), whereby a barbed portion 721f is formed on the wall surface 721e. In addition, in FIG. 4, the sub-recess 725 located on the lower side of the main recess 721 deforms the lower wall surface 721g of the recess 721′ upward, whereby a barbed portion 721h is formed on the wall surface 721g.

Dimensions and depths of the bottom surfaces of the main recess 721 and the sub-recesses 722 to 725 are not limited to a combination of specific values. Assuming that the shape of the opening end of the recess 721′ to be the main recess 721 and the shape of the opening end of the sub-recesses 722 to 725 in plan view are each substantially square, it is sufficient if a length L2 of the side of the sub-recesses 722 to 725 is shorter than a length L1 of the side of the recess 721′. It is sufficient if a distance L3 between the center (the position of the vertex angle) of the sub-recesses 722 to 725 and the side of the recess 721′ in plan view is L3<L2/2. A gap L4 between two adjacent recesses 721′ to be main recesses 721 is set to be longer than the length L1 of the side of the recess 721′ to such an extent that the sub-recess that deforms the wall surface of one recess 721′ and the sub-recess that deforms the wall surface of the other recess 721′ do not communicate with each other to form one recess. For example, when the length L1 of the side of the recess 721′ is 0.12 mm and the length L2 of the side of the sub-recesses 722 to 725 is 0.08 mm, the gap L4 is set to 0.18 mm, for example. Note that a combination of the values of the lengths L1 and L2 of the sides, the distance L3, and the gap L4 described above is not limited to a specific combination, and can be appropriately changed.

Next, a method for forming the roughening recess 720 described above as the first example will be described with reference to FIGS. 7 to 16.

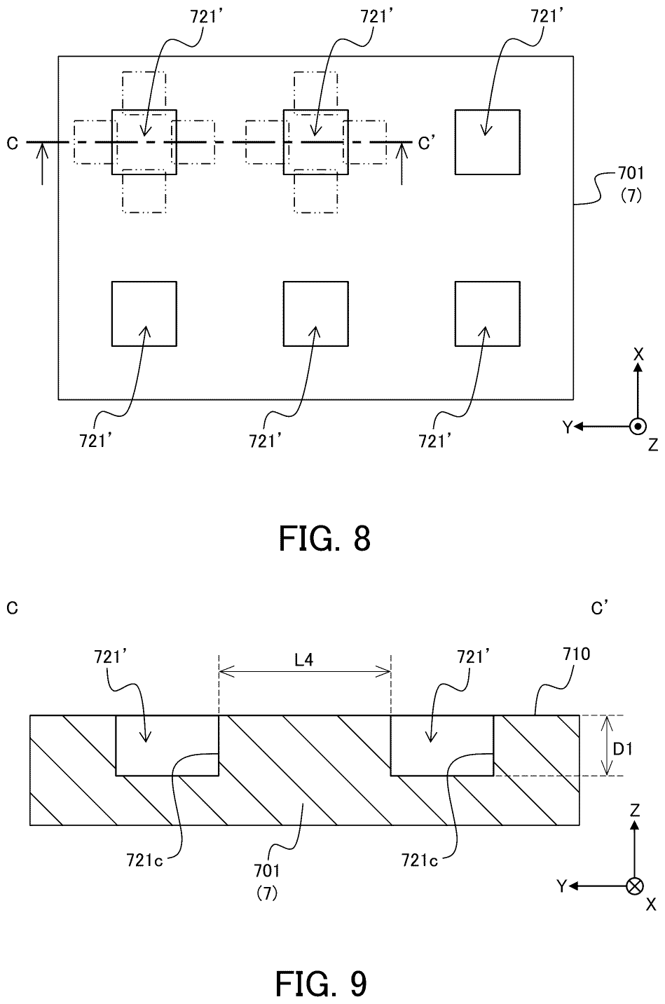

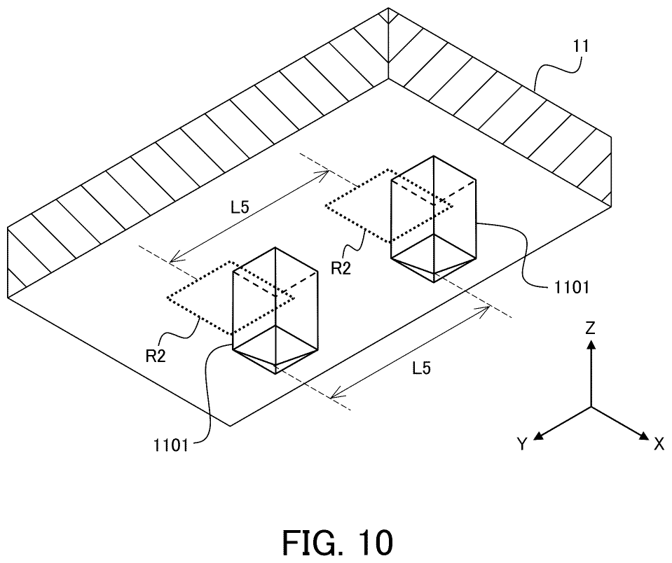

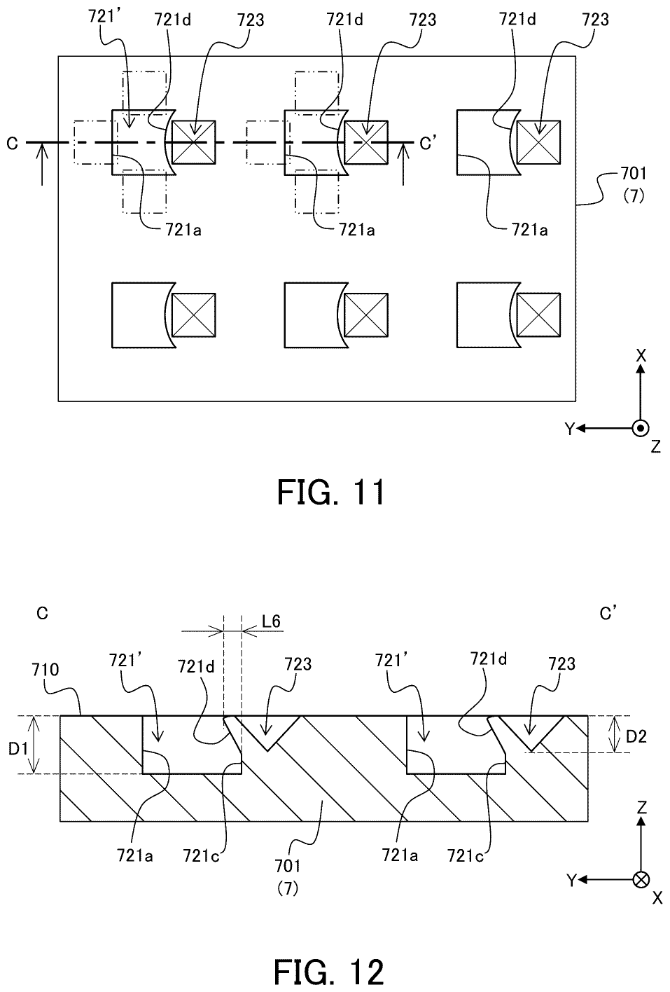

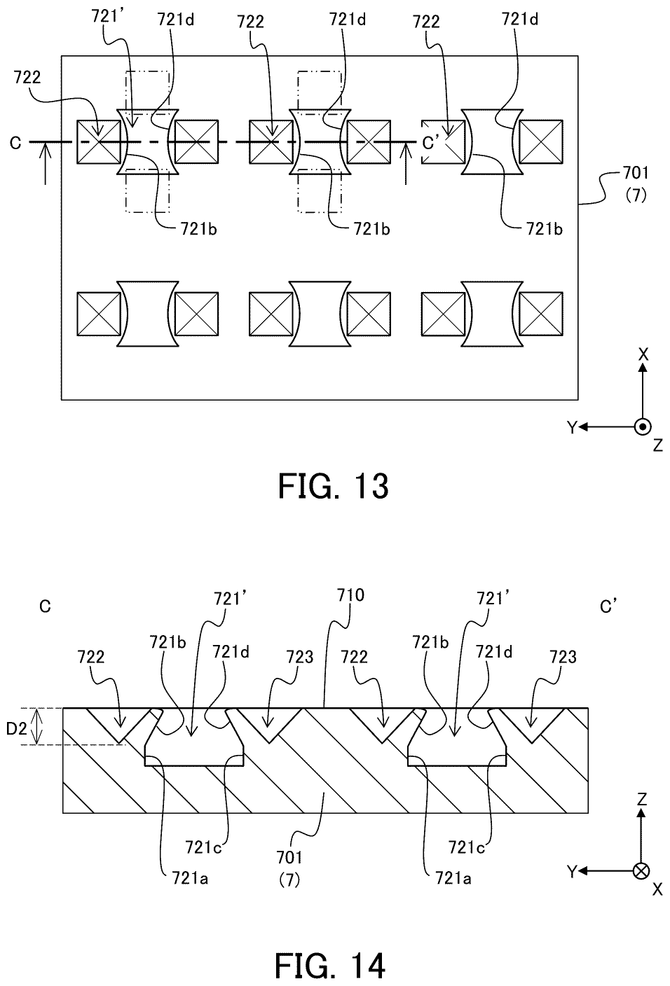

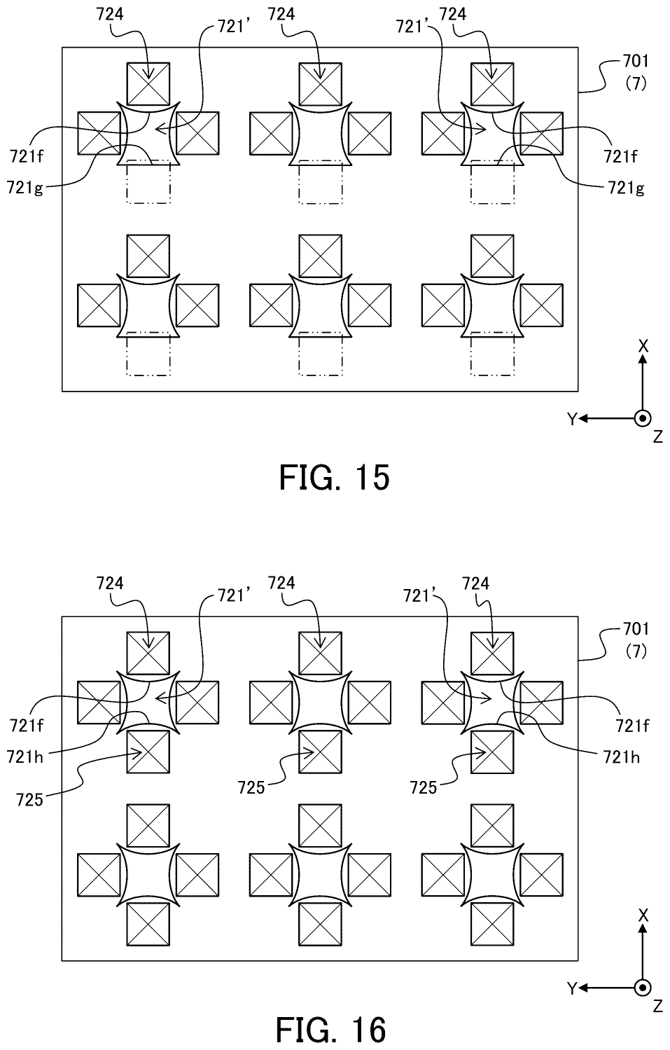

FIG. 7 is a perspective view exemplifying a punch used for forming a recess to be a main recess. FIG. 8 is a partial top view exemplifying recesses formed in a first bonding portion of a lead by the punch exemplified in FIG. 7. FIG. 9 is a cross-sectional view taken along line C-C′ in the portion of the first bonding portion illustrated in FIG. 8. FIG. 10 is a perspective view exemplifying a punch used for forming the sub-recess. FIG. 11 is a partial top view exemplifying sub-recesses formed in the first bonding portion of the lead by the punch exemplified in FIG. 10. FIG. 12 is a cross-sectional view taken along line C-C′ in the portion of the first bonding portion illustrated in FIG. 11. FIG. 13 is a partial top view exemplifying the first bonding portion in which a second sub-recess is formed at each recess. FIG. 14 is a cross-sectional view taken along line C-C′ in the portion of the first bonding portion illustrated in FIG. 13. FIG. 15 is a partial top view exemplifying the first bonding portion in which a third sub-recess is formed at each recess. FIG. 16 is a partial top view exemplifying the first bonding portion in which a fourth sub-recess is formed at each recess.

The step of forming the roughening recess 720 including one main recess 721 and four sub-recesses 722 to 725 described above with reference to FIGS. 3 to 6 includes, for example, a step of forming the recess 721′ to be the main recess 721 and a step of subsequently forming the four sub-recesses 722 to 725.

In the step of forming the recess 721′, for example, as exemplified in FIG. 7, a plurality of recesses 721′ is formed in a two-dimensional lattice shape by using a die 10 in which a plurality of quadrangular prism-shaped punches (pushers) 1001 is disposed adjacent to each other across the gap L4 in each of the X direction and the Y direction. At this time, as exemplified in FIGS. 8 and 9, the recess 721′ defining the quadrangular prism-shaped space having a depth D1 is formed on the upper surface 710 of the first bonding portion 701 of the lead 7. The depth D1 of the recess 721′ is set to be sufficiently smaller than the thickness of the first bonding portion 701, which is not illustrated, for example, about 0.05 mm. The plurality of recesses 721′ may be formed at one time on the entire upper surface 710 of the first bonding portion 701, or may be formed in a plurality of times.

In the step of forming the four sub-recesses 722 to 725, the four sub-recesses 722 to 725 for one recess 721′ are formed one by one in four times. In this case, in the step of forming the sub-recess once, for example, as exemplified in FIG. 10, a die 11 including a plurality of punches 1101 in which one punch 1101 is disposed with respect to a region R2 corresponding to the punch 1001 for forming one recess 721′ is used. The punch 1101 has, for example, a protruding quadrangular pyramid shape at the tip, and is arranged in an orientation in which each side of the quadrangular pyramid at the tip is parallel to any of the four sides of the opening end of the recess 721′ when the die 11 is disposed above the first bonding portion 701 of the lead 7. The punches 1101 are arranged at the same interval L5 as the interval L5 of the punches 1001 for forming the recesses 721′. The interval L5 is the distance between the centers of the two punches 1001 adjacent across the gap L4 as described above with reference to FIG. 7.

FIGS. 11 and 12 illustrate an example in which the sub-recesses 723 on the right side (negative side in the Y direction) of the recesses 721′ in plan view are formed as the first sub-recesses for each of the recesses 721′ using the punches 1101 of the die 11. In this example, the first bonding portion 701 of the lead 7 and the die 11 are aligned so that the vertex of the quadrangular pyramid at the tip of the punch 1101 is outside the opening end of the recess 721′ and is at a position (see FIG. 6) of the distance L3 from the right side of the opening end in plan view, thereby forming the sub-recess 723. At this time, one of the triangular inclination surfaces of the quadrangular pyramid of the tip portion of the punch 1101 displaces the metal material portion between the inclination surface and the wall surface 721c of the recess 721′ in the direction of the wall surface 721a facing the wall surface 721c. As a result, the barbed portion 721d protruding in the direction of the wall surface 721a is formed on the wall surface 721c.

The relationship between a depth D2 of the sub-recess 723 and the depth D1 of the recess 721′ is not limited to the relationship of D2<D1 exemplified in FIG. 12. The depth D2 of the sub-recess 723 may be D2=D1 or D2≈D1. The position of the sub-recess 723 with respect to the recess 721′, the dimensional ratio of the opening end, the depth ratio, the angle of the vertex angle of the quadrangular pyramid of the tip of the punch 1101, and the like can be appropriately changed according to, for example, a desired protrusion amount L6 from the wall surface 721c of the barbed portion 721d. In addition, by forming the sub-recess 723, the barbed portion 721d in which the entire wall surface 721c protrudes to the opposing wall surface 721a side may be formed.

FIGS. 13 and 14 illustrate an example in which the sub-recesses 722 on the left side (positive side in the Y direction) of the recesses 721′ in plan view are formed as the second sub-recesses for each of the recesses 721′ using the punches 1101 of the die 11. In this example, the first bonding portion 701 of the lead 7 and the die 11 are aligned so that the vertex of the quadrangular pyramid at the tip of the punch 1101 is outside the opening end of the recess 721′ and is at a position (see FIG. 6) of the distance L3 from the left side of the opening end in plan view, thereby forming the sub-recess 722. The sub-recess 722 is formed to have the depth D2 under, for example, the same processing condition (pressurization condition) as when the sub-recess 723 is formed. At this time, one of the triangular inclination surfaces of the quadrangular pyramid of the tip portion of the punch 1101 displaces the metal material portion between the inclination surface and the wall surface 721a of the recess 721′ in the direction of the wall surface 721c where the barbed portion 721d is formed and facing the wall surface 721a. As a result, the barbed portion 721b protruding in the direction of the wall surface 721c is formed on the wall surface 721a.

FIG. 15 illustrates an example in which the sub-recesses 724 on the upper side (positive side in the X direction) of the recesses 721′ in plan view are formed as the third sub-recesses for each of the recesses 721′ using the punches 1101 of the die 11. In this example, the first bonding portion 701 of the lead 7 and the die 11 are aligned so that the vertex of the quadrangular pyramid at the tip of the punch 1101 is outside the opening end of the recess 721′ and is at a position (see FIG. 6) of the distance L3 from the upper side of the opening end in plan view, thereby forming the sub-recess 724. The sub-recess 724 is formed to have the depth D2 under, for example, the same processing condition (pressurization condition) as when the sub-recesses 722 and 723 are formed. At this time, one of the triangular inclination surfaces of the quadrangular pyramid of the tip portion of the punch 1101 displaces the metal material portion between the inclination surface and the wall surface 721e of the recess 721′ in the direction of the wall surface 721g facing the wall surface 721e. As a result, the barbed portion 721f protruding in the direction of the wall surface 721g is formed on the wall surface 721e.

FIG. 16 illustrates an example in which the sub-recesses 725 on the lower side (negative side in the X direction) of the recesses 721′ in plan view are formed as the fourth sub-recesses for each of the recesses 721′ using the punches 1101 of the die 11. In this example, the first bonding portion 701 of the lead 7 and the die 11 are aligned so that the vertex of the quadrangular pyramid at the tip of the punch 1101 is outside the opening end of the recess 721′ and is at a position (see FIG. 6) of the distance L3 from the lower side of the opening end in plan view, thereby forming the sub-recess 725. The sub-recess 725 is formed to have the depth D2 under, for example, the same processing condition (pressurization condition) as when the sub-recesses 722 to 724 are formed. At this time, one of the triangular inclination surfaces of the quadrangular pyramid of the tip portion of the punch 1101 displaces the metal material portion between the inclination surface and the wall surface 721g of the recess 721′ in the direction of the wall surface 721e where the barbed portion 721f is formed and facing the wall surface 721g. As a result, the barbed portion 721h protruding in the direction of the wall surface 721e is formed on the wall surface 721g.

Note that, in the above examples, the sub-recesses 722 to 725 are formed under such processing conditions that the depth becomes D2, but the depths of all the sub-recesses may not be the same. For example, in the example illustrated in FIG. 3, when the stress (thermal strain) generated at the interface between the upper surface 710 of the first bonding portion 701 and the sealing material 9 is different between the X direction and the Y direction, delamination of the sealing material 9 at one of the end in the X direction and the end in the Y direction may be more likely to occur than delamination of the sealing material 9 at the other end. Alternatively, delamination of the sealing material 9 may easily occur on the outer peripheral side between the outer peripheral side and the inner side of the upper surface 710 of the roughening recess 720. In such a case, the barbed portion formed on the wall surface may be enlarged by making the sub-recess on the side along the same side of the roughening recess 720 along the side located at the end in the direction in which larger stress (thermal strain) is generated slightly deeper than D2.

When the four sub-recesses 722 to 725 are formed with respect to each of the recesses 721′ in the above-described procedure, the barbed portions 721b, 721d, 721f, and 721h protruding in the direction of the opposing wall surface are formed on the four respective wall surfaces 721a, 721c, 721e, and 721g of the recess 721′. As a result, the recess 721′ formed in the first bonding portion 701 of the lead 7 by the quadrangular prism-shaped punch 1001 as exemplified in FIG. 7 becomes the main recess 721 having the barbed portions 721b, 721d, 721f, and 721h described above with reference to FIGS. 4 and 5.

As described above, the plurality of roughening recesses 720 including the main recesses 721 having the barbed portions 721b, 721d, 721f, and 721h on the wall surfaces are formed on the upper surface 710 of the first bonding portion 701 of the lead 7 according to the present embodiment. When the insulating material as the sealing material 9 is loaded in the main recess 721 of the roughening recess 720, the loaded portion is restricted from moving in a direction (positive side in the Z direction) in which the loaded portion comes out of the main recess 721 by the barbed portions 721b, 721d, 721f, and 721h, and is less likely to come out of the main recess 721. In addition, in the roughening recess 720, the four sub-recesses 722 to 725 each defining a quadrangular pyramid-shaped space are formed at positions outside the main recess 721 in plan view. By forming such sub-recesses 722 to 725, the area of the interface between the upper surface 710 of the first bonding portion 701 of the lead 7 and the sealing material 9 in the region where one roughening recess 720 is formed increases, and the adhesion between the first bonding portion 701 and the sealing material 9 is enhanced. Accordingly, in the semiconductor device 1 (semiconductor module 2) of the present embodiment, for example, as compared with the case where only the recess 721′ defining the quadrangular prism-shaped space exemplified in FIGS. 8 and 9 is formed on the upper surface 710 of the first bonding portion 701 by the punch 1001 exemplified in FIG. 7, it is possible to make the delamination at the interface between the first bonding portion 701 of the lead 7 and the sealing material 9 less likely to occur, and it is possible to suppress the occurrence of failure or the like due to the delamination. In particular, the roughening recess 720 according to the present embodiment can further enhance the adhesion between the coating agent such as PA for coating the surface of the lead 7 or the like in order to prevent an increase in distortion generated in a failure part due to delamination of the sealing resin such as an epoxy resin as the sealing material 9 from the first bonding portion 701 and the upper surface 710 of the first bonding portion 701.

In addition, as in the embodiment described above, in a case where the sub-recess is formed using the die 11 aligned such that the center of the punch 1101 is located outside the recess 721′ in plan view and at the position of the distance L3 from the wall surface of the recess 721′, the step of forming the plurality of sub-recesses for one recess 721′ can be performed in a plurality of times. For this reason, the restriction of the processing dimension at the time of forming the sub-recess becomes relatively loose, and the barbed portion having a desired protrusion amount can be easily formed.

Note that the punch 1101 having a quadrangular pyramid-shaped tip described above with reference to FIG. 10 is merely an example of a punch that can be used for forming the sub-recesses 722 to 725 for forming the main recess 721 having the barbed portions 721b, 721d, 721f, and 721h on the wall surfaces. The shape of the tip of the punch (pusher) used for forming the sub-recesses 722 to 725 may be another shape.

FIG. 17 is a perspective view illustrating another example of a punch used for forming the sub-recess. In a die 12 exemplified in FIG. 17, punches 1201 having a chevron shape (wedge shape) in which the tip is configured by two planes are arranged in a two-dimensional lattice shape. Regarding the punch 1201 exemplified in FIG. 17, similarly to the punch 1101 of the die 11 exemplified in FIG. 11, one punch 1201 is disposed with respect to the region R2 corresponding to the punch 1001 for forming one recess 721′. The punches 1201 are arranged at the same interval L5 as the interval L5 of the punches 1001 for forming the recesses 721′. The interval L5 is the distance between the centers of the two punches 1001 adjacent across the gap L4. In this case, the plurality of punches 1201 is disposed in a two-dimensional lattice shape such that the extending directions of the ridge lines of the tips are the same direction (X direction in FIG. 17).

When the sub-recess is formed using the die 12 exemplified in FIG. 17, the first bonding portion 701 of the lead 7 and the die 12 are aligned so that the ridge line of the tip of the punch 1201 is outside the opening end of the recess 721′ and is parallel to the side corresponding to the side surface on which the barbed portion is formed by the punch 1201 at the position of the distance L3 from the side, thereby forming the sub-recess. At this time, although not illustrated, the sub-recess formed by each punch 1201 is a valley-shaped space having a valley line extending in a direction parallel to the ridge line of the tip of the punch 1201. In this case, the plane located between the ridge line and the wall surface of the recess 721′ of the two planes constituting the chevron shape of the tip of the punch 1201 displaces the metal material portion between the plane and the wall surface of the recess 721′ to form the barbed portion. When the barbed portion is formed on each of the four wall surfaces of the recess 721′ using the die 12 including the punches 1201 exemplified in FIG. 17, for example, a first die in which the extending direction of the ridge line of the punch 1201 is set to a first direction in order to form the barbed portion on the side surface parallel to the first direction (X direction) in the recess 721′ and a second die in which the extending direction of the ridge line of the punch 1201 is set to a second direction in order to form the barbed portion on the side surface parallel to the second direction (Y direction) in the recess 721′ may be prepared. In addition, when the barbed portion is formed on each of the four wall surfaces of the recess 721′ using the die 12 including the punches 1201 exemplified in FIG. 17, for example, in the step of forming the barbed portion on the side surface parallel to the first direction (X direction) in the recess 721′ and the step of forming the barbed portion on the side surface parallel to the second direction (Y direction) in the recess 721′, a common die 12 may be used, and the die 12 may be rotated so that the extending direction of the ridge line of the punch 1201 becomes parallel to the side surface on which the barbed portion is formed in each step.

In addition, in the above-described embodiment, an example is described in which at least two sub-recesses are formed for one recess 721′ by one die. However, each of the four sub-recesses for one recess 721′ may be formed by different dies. In this case, it is sufficient if the tip of the punch of one die used for forming one sub-recess has a shape capable of forming the barbed portion on one desired wall surface of the recess 721′. For example, the sub-recess may be formed using a die in which punches having a single edge shape are two-dimensionally arranged instead of the punches 1201 having a chevron shape at the tip exemplified in FIG. 17.

Further, the arrangement of the plurality of roughening recesses 720 described in the above-described embodiment is not limited to the arrangement in a two-dimensional lattice shape on the entire upper surface 710 of the first bonding portion 701 of the lead 7 as exemplified in FIG. 3. The plurality of roughening recesses 720 may be arranged only in a predetermined region on the upper surface 710. Further, the roughening recess 720 including the main recess 721 and the sub-recesses 722 to 725 and the recess (for example, the recess 721′ defining the quadrangular prism-shaped space described above) not including the sub-recess and having no barbed portion formed on the wall surface may be arranged on the upper surface 710 of the first bonding portion 701. That is, in the above-described embodiment, the recess 721′ defining the quadrangular space may be formed on the upper surface 710 of the first bonding portion 701 as a second roughening recess apart from the roughening recess 720.

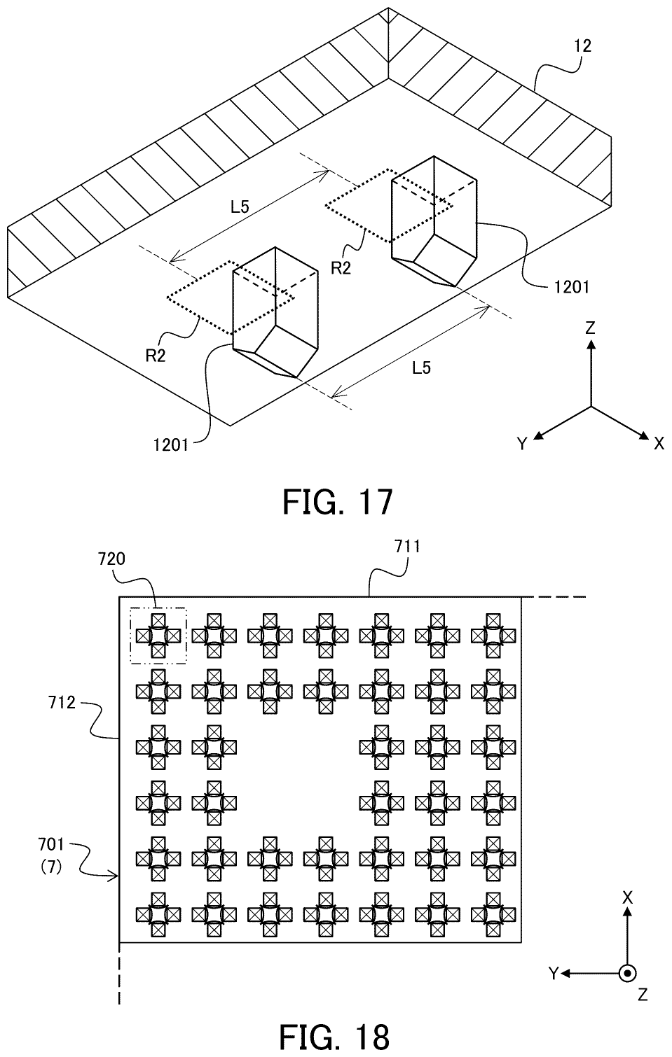

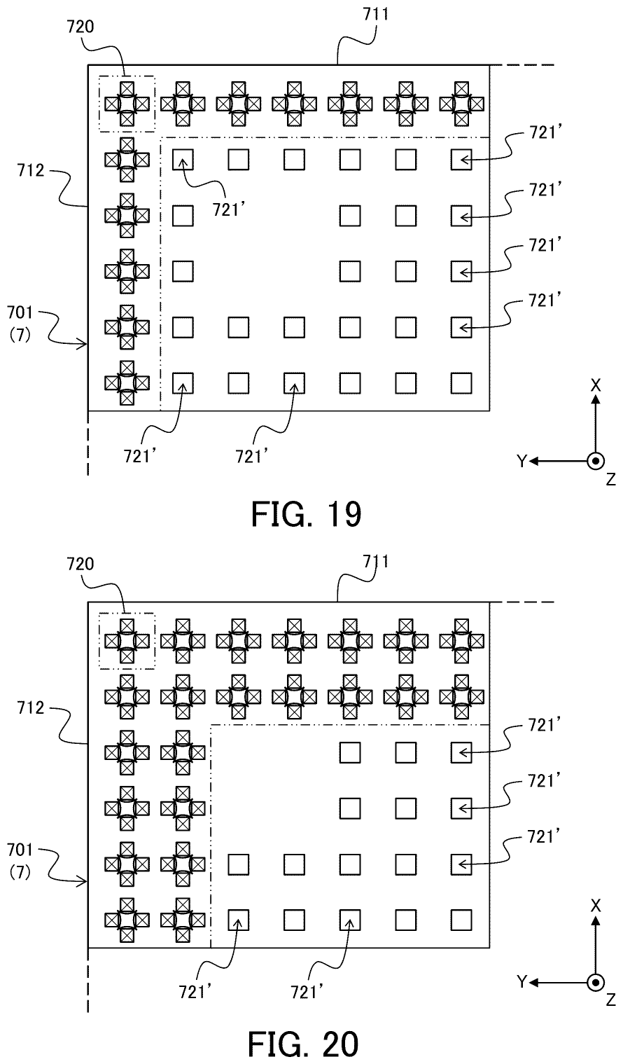

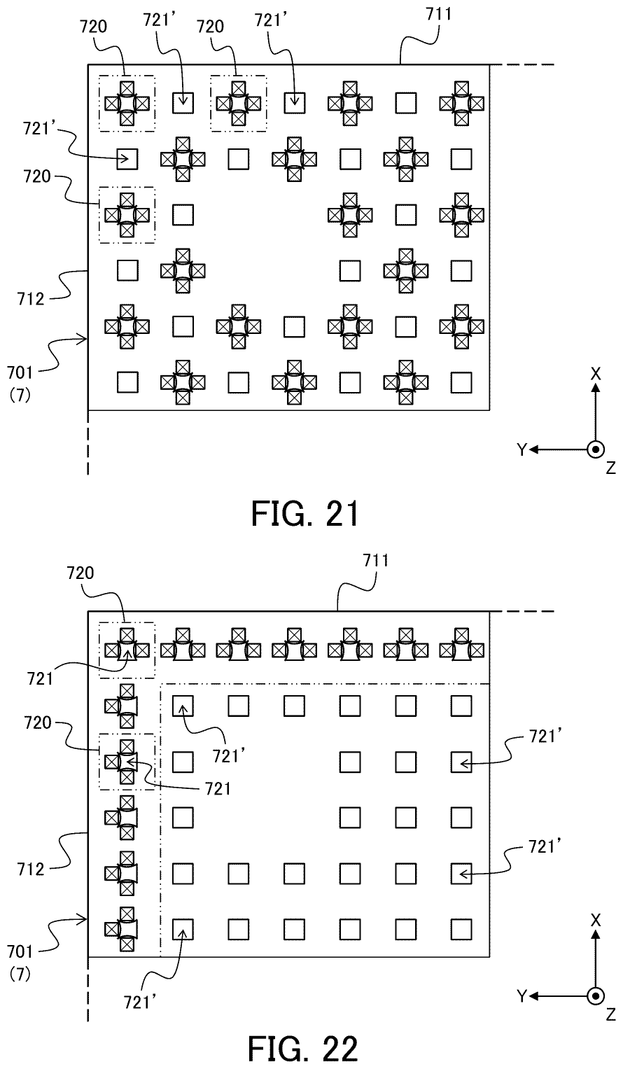

FIG. 18 is a partial top view describing a first modification of arrangement of roughening recesses. FIG. 19 is a partial top view describing a second modification of arrangement of roughening recesses. FIG. 20 is a partial top view describing a third modification of arrangement of roughening recesses. FIG. 21 is a partial top view describing a fourth modification of arrangement of roughening recesses. FIG. 22 is a partial top view describing a fifth modification of arrangement of roughening recesses.

FIG. 18 illustrates an example in which the roughening recesses 720 are not disposed at some of the lattice points of the two-dimensional lattice at which the roughening recesses 720 are disposed. The upper surface 710 of the first bonding portion 701 of the lead 7 is generally a flat surface, and as exemplified in FIG. 3, the roughening recesses 720 can be formed in a two-dimensional lattice shape on the entire upper surface 710. However, in some types of leads 7, for example, a region having a function different from that of the roughening recess may be partially provided on the upper surface 710 of the first bonding portion 701. In such a region provided on the upper surface 710 of the first bonding portion 701 of the lead 7, a roughening recess such as the roughening recess 720 may not be formed. In such a case, for example, as exemplified in FIG. 18, the roughening recess 720 may not be formed in the region where the roughening recess 720 cannot be formed.

FIGS. 19 and 20 illustrate examples in which the roughening recesses 720 including the main recesses 721 and the sub-recesses 722 to 725 and the recesses 721′ having no barbed portions using the sub-recesses are arranged in a two-dimensional lattice shape on the upper surface 710 of the first bonding portion 701 of the lead 7. It is known that the delamination at the interface between the upper surface 710 of the first bonding portion 701 and the sealing material 9 occurs at the outer peripheral portion of the upper surface 710 of the first bonding portion 701, and propagates in a direction orthogonal to the side of the upper surface 710. Therefore, as exemplified in FIGS. 19 and 20, by arranging the roughening recesses 720 including the main recesses 721 having the above-described barbed portions and the sub-recesses 722 to 725 along the outer peripheral portion of the upper surface 710 of the first bonding portion 701, it is possible to suppress delamination of the sealing material 9 at the outer peripheral portion of the upper surface 710. When the delamination of the sealing material 9 at the outer peripheral portion of the upper surface 710 of the first bonding portion 701 can be suppressed, the propagation of delamination is also reduced. Therefore, in a region of the upper surface 710 surrounded by the roughening recesses 720 arranged along the outer peripheral portion, for example, the recesses 721′ having no barbed portions formed by the punches 1001 exemplified in FIG. 7 may be arranged as second roughening recesses in order to prevent delamination at the interface between the conductive material as the lead 7 and the sealing material 9.

As one specific example, FIG. 19 illustrates an example in which one row along a side 711 closest to the side 711 and one row along a side 712 closest to the side 712 in the two-dimensional lattice set on the upper surface 710 of the first bonding portion 701 in plan view are the roughening recesses 720. In this example, only the recesses annularly disposed on the outermost periphery among the recesses for preventing the delamination of the sealing material 9 and disposed in the two-dimensional lattice shape on the upper surface 710 of the first bonding portion 701 are the roughening recesses 720 including the main recesses 721 and the sub-recesses 722 to 725, and the recesses 721′ having no barbed portions are arranged in the region surrounded by the annularly disposed roughening recesses 720. The recesses 721′ having no barbed portions are not disposed in a region where a recess for preventing delamination of the sealing material 9 cannot be formed on the upper surface 710 of the first bonding portion 701.

In addition, FIG. 20 illustrates an example in which two rows along the side 711 and two columns along the side 712 of the two-dimensional lattice set on the upper surface 710 of the first bonding portion 701 in plan view are the roughening recesses 720. In this example, only the recesses annularly disposed on the outermost periphery and the second outer periphery adjacent to the outermost periphery among the recesses for preventing the delamination of the sealing material 9 and disposed in the two-dimensional lattice shape on the upper surface 710 of the first bonding portion 701 are the roughening recesses 720 including the main recesses 721 and the sub-recesses 722 to 725, and the recesses 721′ having no barbed portions are arranged in the region surrounded by the annularly disposed roughening recesses 720. The recesses 721′ having no barbed portions are not disposed in a region where a recess for preventing delamination of the sealing material 9 cannot be formed on the upper surface 710 of the first bonding portion 701.

Note that the number of rows and the number of columns in which the roughening recesses 720 including the main recesses 721 having the barbed portions and the sub-recesses 722 to 725 are disposed on the upper surface 710 of the first bonding portion 701 in plan view are not limited to a specific combination. The number of rows and the number of columns in which the roughening recesses 720 are disposed may be set according to, for example, the dimension in the first direction (X direction) and the dimension in the second direction (Y direction) orthogonal to the first direction of the upper surface 710 of the first bonding portion 701. For example, in the examples illustrated in FIGS. 19 and 20, when the stress (thermal strain) generated at the interface between the upper surface 710 of the first bonding portion 701 and the sealing material 9 is different between the X direction and the Y direction, delamination of the sealing material 9 at one of the end in the X direction and the end in the Y direction may be more likely to occur than delamination of the sealing material 9 at the other end. In such a case, the number of rows or the number of columns of the roughening recesses 720 along the side located at the end in the direction in which larger stress (thermal strain) is generated may be larger than the number of columns or the number of rows of the roughening recesses 720 along the side located at the end in the direction in which smaller stress (thermal strain) is generated.

FIG. 21 illustrates still another example in which the roughening recesses 720 including the main recesses 721 and the sub-recesses 722 to 725 and the recesses 721′ having no barbed portions using the sub-recesses are arranged in a two-dimensional lattice shape on the upper surface 710 of the first bonding portion 701 of the lead 7. In FIG. 21, in the direction of the unit translation vector representing the two-dimensional lattice in which the roughening recesses 720 and the recesses 721′ are arranged (X direction and Y direction), the roughening recesses 720 having the barbed portions and the recesses 721′ having no barbed portions are disposed adjacent to each other. In other words, in the first direction (X direction) and the second direction (Y direction) on the upper surface 710 of the first bonding portion 701, the roughening recesses 720 having the barbed portions and the recesses 721′ having no barbed portions are alternately disposed. The arrangement of the roughening recesses 720 and the arrangement of the recesses 721′ exemplified in FIG. 21 may be referred to as a staggered arrangement.

FIG. 22 illustrates a modification of the roughening recesses 720 including the main recesses 721 having the barbed portions on the wall surfaces by the sub-recesses. In the roughening recess 720 described above with reference to FIGS. 3 to 5 and the like, the barbed portions 721b, 721d, 721f, and 721h protruding to the opposing wall surface sides are formed by the sub-recesses on the four respective wall surfaces 721a, 721c, 721e, and 721g of the recess 721′ defining the quadrangular prism-shaped space. On the other hand, in the roughening recesses 720 exemplified in FIG. 22, only three wall surfaces among the four wall surfaces 721a, 721c, 721e, and 721g of one recess 721′ are formed with the barbed portions protruding to the opposing wall surface sides by the sub-recesses. In each of the roughening recesses 720 exemplified in FIG. 22, the sub-recess is formed at least between the main recess 721 and a side closest to the main recess 721 among the sides of the upper surface 710 of the first bonding portion 701. Note that the positions and the number of sub-recesses with respect to the main recess 721 in the roughening recess 720 are not limited to the positions and the number exemplified in FIG. 22.

Note that the roughening recesses 720 described above with reference to the drawings are merely examples of the roughening recess including the main recess in which the barbed portion protruding toward the opposing wall surface is formed on one or more wall surfaces of the recess and the sub-recess having a center at a position outside the main recess in plan view and away from the wall surface on which the barbed portion is formed by the predetermined distance L3, and having the inclined surface that becomes shallower from the center toward the opening end of the main recess. The relationship between the main recess and one or more sub-recesses in the roughening recess 720 is not limited to the examples described above with reference to the drawings, and various changes and modifications can be made. Further, the recess on which the barbed portion by the sub-recess is not formed is not limited to the recess 721′ that defines the quadrangular prism-shaped space used for forming the main recess 721, but may be a recess that defines a space having another shape.

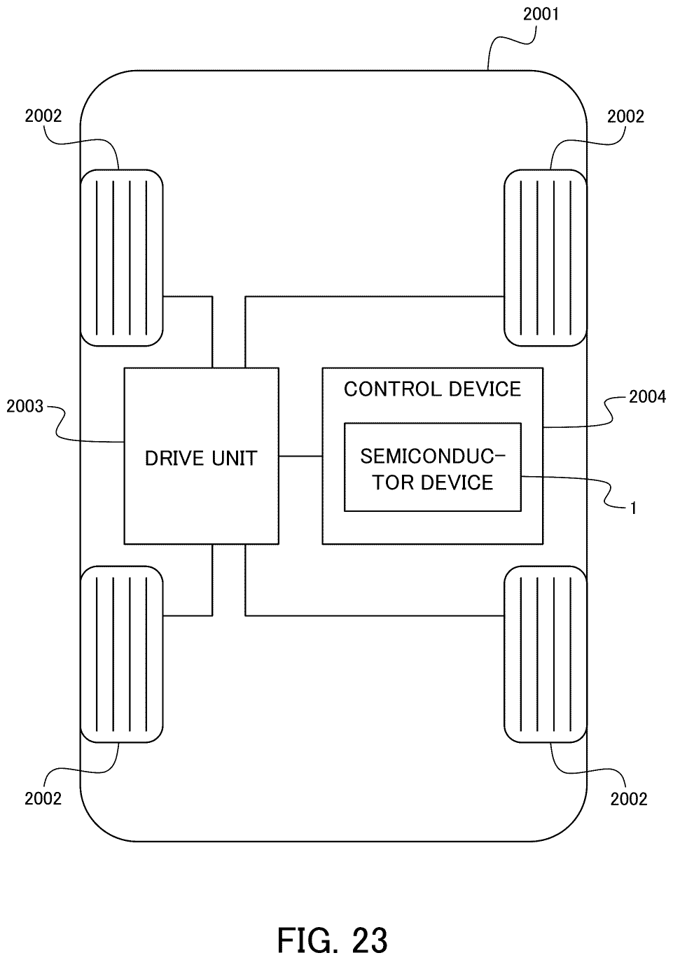

As described above, the semiconductor device 1 including the semiconductor module 2 of the present embodiment can be applied to the power conversion device such as the inverter of the in-vehicle motor. A vehicle to which the semiconductor device 1 of the present invention is applied will be described with reference to FIG. 23.

FIG. 23 is a schematic plan view illustrating an example of a vehicle to which the semiconductor device according to the present invention is applied. A vehicle 2001 illustrated in FIG. 23 is configured with, for example, a four-wheeled vehicle including four wheels 2002. The vehicle 2001 may be, for example, an electric vehicle that drives wheels with a motor or the like, or a hybrid vehicle using power of an internal combustion engine in addition to the motor.

The vehicle 2001 includes a drive unit 2003 that imparts power to the wheels 2002 and a control device 2004 that controls the drive unit 2003. The drive unit 2003 may be configured with, for example, at least one of an engine, a motor, and a hybrid of the engine and the motor.

The control device 2004 performs control (for example, power control) of the drive unit 2003 described above. The control device 2004 includes the semiconductor device 1 described above. The semiconductor device 1 may be configured to perform the power control on the drive unit 2003.

In the semiconductor module 2 of the semiconductor device 1 used for this type of vehicle 2001, when the first bonding portion 701 of the lead 7 described above is bonded to the electrode (for example, the second main electrode of the semiconductor element 510) on the upper surface of the semiconductor element by the bonding material S3, it is possible to prevent the propagation of delamination at the interface between the sealing material 9 and the upper surface 710 of the first bonding portion 701. Therefore, it is possible to reduce the frequency of inspection and replacement of the semiconductor device 1 used in the vehicle 2001.

Note that the vehicle to which the semiconductor device 1 is applied is not limited to the four-wheeled vehicle exemplified in FIG. 23. The vehicle to which the semiconductor device 1 is applied includes, for example, a two-wheeled vehicle and a railway vehicle.

Although the present embodiment and the modifications have been described above, the above-described embodiment and modifications may be wholly or partially combined as another embodiment.

In addition, the present embodiment is not limited to the above-described embodiment and modifications, and various changes, substitutions, and modifications may be made without departing from the spirit of the technical idea. In addition, if the technical idea can be achieved in another manner by the progress of the technology or another derived technology, the technology may be implemented by using the method. Therefore, the claims cover all embodiments that may be included within the scope of the technical idea.

The feature points in the above embodiment will be described below.

A semiconductor module according to the above embodiment includes: a circuit board on which a semiconductor element is mounted; a lead that is bonded to an electrode on an upper surface of the semiconductor element by a bonding material; and a sealing material that seals the semiconductor element and the lead, in which in the lead, a roughening recess that prevents delamination at an interface between the lead and the sealing material is formed on an upper surface of a first bonding portion bonded to the electrode, the upper surface being opposite to a lower surface facing the electrode, and the roughening recess includes a main recess in which a barbed portion protruding toward an opposite wall surface is formed on one or more wall surfaces of a recess and a sub-recess having a center located outside the main recess in plan view and at a position away from the wall surface on which the barbed portion is formed by a predetermined distance, and having an inclined surface that becomes shallower from the center toward an opening end of the main recess.

In the semiconductor module according to the above embodiment, the main recess has a bottom surface having a flat quadrangular shape, the sub-recess has an opening end having a quadrangular shape and has a shape defining a quadrangular pyramid-shaped space having the opening end as a bottom surface, and each side of the opening end of the sub-recess is substantially parallel to any of sides of the bottom surface of the main recess.

In the semiconductor module according to the above embodiment, the main recess has a bottom surface having a flat quadrangular shape, and the sub-recess has an opening end having a quadrangular shape and has a shape defining a valley type space having a valley line substantially parallel to a side of the opening end and a side of the bottom surface of the main recess.

In the semiconductor module according to the above embodiment, the main recess has a shape in which the barbed portion is formed on each of four wall surfaces of a recess defining a quadrangular prism-shaped space.

In the semiconductor module according to the above embodiment, a gap between main recesses of two adjacent roughening recesses is longer than a dimension of the main recess in a direction in which the two roughening recesses are adjacent to each other.

In the semiconductor module according to the above embodiment, the roughening recess is disposed at a position corresponding to a lattice point of a two-dimensional lattice set on the upper surface of the first bonding portion of the lead.

In the semiconductor module according to the above embodiment, the roughening recess in which the barbed portion is formed and a second roughening recess not having the barbed portion are disposed adjacent to each other at positions corresponding to lattice points of the two-dimensional lattice.

In the semiconductor module according to the above embodiment, the roughening recesses are annularly disposed along a side of the upper surface of the first bonding portion.

In the semiconductor module according to the above embodiment, a second roughening recess not having the barbed portion is disposed in a region surrounded by the roughening recesses annularly disposed on the upper surface of the first bonding portion.

A semiconductor device according to the embodiment includes: the semiconductor module described above; and a cooler that is disposed on a surface of the circuit board of the semiconductor module on a side opposite to a surface on which the semiconductor element is mounted.

A vehicle according to the embodiment includes the semiconductor module or the semiconductor device described above.

### INDUSTRIAL APPLICABILITY

As described above, the present invention has the effect of being able to prevent delamination at an interface between an upper surface of a bonding portion of a lead bonded to an electrode of a semiconductor element and a sealing material, and is particularly useful for a semiconductor module for industrial or electrical equipment, a semiconductor device, and a vehicle.

The present application is based on Japanese Patent Application No. 2022-170593 filed on Oct. 25, 2022. All the contents are included herein.

1. A semiconductor module comprising:
a circuit board including a semiconductor element, the semiconductor element having an electrode on an upper surface thereof;
a lead that is bonded to the electrode of the semiconductor element by a bonding material; and
a sealing material that seals the semiconductor element and the lead, wherein
the lead includes:
a bonding portion bonded to the electrode, the bonding portion having a lower surface facing the electrode, and an upper surface opposite to the lower surface, and
a roughening recess formed on the upper surface of the bonding portion, for preventing delamination at an interface between the lead and the sealing material, wherein
the roughening recess includes:
a main recess having:
a first wall surfaces and a second wall surface opposite to each other, and
a barbed portion formed on the first wall surface and protruding toward the second wall surface, and
a sub-recess having:
a center, which is located, in a plan view of the semiconductor module, outside the main recess and at a position away from the first wall surface by a predetermined distance, and
an inclined surface that becomes shallower from the center toward an opening end of the main recess.

2. The semiconductor module according to claim 1, wherein
the main recess further has a bottom surface that is of a flat quadrangular shape, and
the sub-recess has an opening end that is of a quadrangular shape, four sides of the opening end of the sub-recess being substantially parallel to four sides of the bottom surface of the main recess, respectively.

3. The semiconductor module according to claim 1, wherein
the main recess has a bottom surface that is of a flat quadrangular shape, and
the sub-recess has an opening end that is of a quadrangular shape, and has a bottom surface that is of a valley shape, a valley line of the valley shape being substantially parallel to a side of the opening end of the sub-recess and a side of the bottom surface of the main recess.

4. The semiconductor module according to claim 1, wherein
the main recess further has a third wall surface and a fourth wall surface opposite to each other, the first to fourth wall surfaces defining a quadrangular prism-shaped space, and
the barbed portion is formed on each of first to fourth wall surfaces of the main recess.

5. The semiconductor module according to claim 1, wherein
the roughening recess is a first roughening recess,
the semiconductor module further has a second roughening recess adjacent to the first roughening recess, the second roughening recess having a same configuration as the first roughening recess, and being aligned with the first roughening recess in an alignment direction, and
a gap between the main recesses of the first and second roughening recesses is longer than a dimension of each of the main recesses in the alignment direction.

6. The semiconductor module according to claim 1, wherein
the roughening recess is disposed at a position corresponding to a lattice point of a two-dimensional lattice set on the upper surface of the bonding portion of the lead.

7. The semiconductor module according to claim 6, wherein
the roughening recess is a first roughening recess,
the semiconductor module further has a second roughening recess that has a same configuration as the first roughening recess, except that the second roughening recess is free of the barbed portion, and
the first roughening recess and the second roughening recess are disposed adjacent to each other at positions corresponding to lattice points of the two-dimensional lattice.

8. The semiconductor module according to claim 1, wherein
the lead includes a plurality of roughening recesses each having a same configuration as said roughening recess,
the plurality of roughening recesses are disposed on an outermost periphery of the upper surface of the bonding portion.

9. The semiconductor module according to claim 8, wherein
each of the plurality of roughening recesses is a first roughening recess,
the semiconductor module further has a second roughening recess that has a same configuration as the first roughening recess, except that the second roughening recess is free of the barbed portion, and
the second roughening recess is disposed in a region surrounded by the first roughening recesses.

10. A semiconductor device comprising:
the semiconductor module according to claim 1, wherein the circuit board further includes a wiring board having
a first surface on which the semiconductor element is mounted, and
a second surface opposite to the first surface; and
a cooler that is disposed on the second surface of the wiring board.

11. A vehicle comprising the semiconductor device according to claim 10.

12. A vehicle comprising the semiconductor module according to claim 1.
